(19) United States
(12) Patent Application Publication
(10) Pub. No.: US 2009/0108947 A1
(43) Pub. Date: Apr. 30, 2009

(54) Voltage Controlled Oscillator

(76) Inventor: Ren-Chieh Liu, Chang-Hua Hsien (TW)

Correspondence Address: NORTH AMERICA INTELLECTUAL PROPERTY CORPORATION, P.O. BOX 506, MERRIFIELD, VA, 22116, US

(21) Appl. No.: 12/257,400

(22) Filed: Oct. 24, 2008

(30) Foreign Application Priority Data
Oct. 26, 2007 (TW) 096140308

(51) Int. Cl. H03B 5/12

(52) U.S. Cl. 331/117 FE

(57) ABSTRACT

A voltage controlled oscillator includes an LC-tank circuit, a cross-coupled pair circuit, and a trans-conductance adjusting circuit. The LC-tank circuit provides an inductance and a capacitance. The cross-coupled pair circuit is coupled to the LC-tank circuit and has a first transistor and a second transistor in a cross-coupled manner. The trans-conductance adjusting circuit is utilized for adjusting a trans-conductance value of the voltage controlled oscillator according to a first control signal, which includes a third transistor coupled to the first transistor and a first switch unit, and a forth transistor coupled to the second transistor and the first switch unit. The first control signal is used for controlling whether to turn on the first switch unit so as to adjust the trans-conductance value of the voltage controlled oscillator.

### Background of the Invention

1. Field of the Invention

The present invention relates to a voltage controlled oscillator, and more particularly, to a voltage controlled oscillator having a wide tuning range.

2. Description of the Prior Art

Within wireless communication facilities, such as a mobile or a wireless LAN card, a voltage controlled oscillator (VCO) is a key element and usually collates with a phase frequency detector (PFD), a charge pump (CP), a low pass filter (LPF), and a frequency divider, to form a frequency synthesizer for generating signals with different frequencies. Hence, improving the efficiency, lowering power consumption, and lowering the cost of the voltage controlled oscillator have become new challenges to the mobile communication market.

In the prior art, varactors or switchable capacitors are usually used for adjusting the resonance frequency of the voltage controlled oscillator. To increasing the tuning range of the voltage controlled oscillator simply by increasing the capacitance results in the VCO being unable to oscillate at lower frequencies due to the capacitance being too large and the swing of the voltage controlled oscillator being too small. In order to solve such problems, some methods are usually adopted, such as increasing the current, increasing the switchable inductor value, and using a latch-type mixer or a quadrature type VCO. These methods easily bring out disadvantages, however, such as larger current consumption, increased area, decreased Q value, and poor phase noise.

### SUMMARY OF THE INVENTION

It is one of the objectives of the claimed invention to provide a voltage controlled oscillator for controlling the voltage swing and the tuning range of the voltage controlled oscillator by adjusting the number of cross-coupled transistor pairs to solve the abovementioned problems.

According to an exemplary embodiment of the present invention, a voltage controlled oscillator is provided. The voltage controlled oscillator includes an LC-tank circuit, a cross-coupled pair circuit, and a trans-conductance adjusting circuit. The LC-tank circuit is used for providing an inductance and a capacitance to determine a resonance frequency. The cross-coupled pair circuit is coupled to the LC-tank circuit and has a first transistor and a second transistor in a cross-coupled manner. The trans-conductance adjusting circuit is coupled to the cross-coupled pair circuit for adjusting a trans-conductance value of the voltage controlled oscillator according to a first control signal. The trans-conductance adjusting circuit includes a third transistor and a fourth transistor. The third transistor is coupled to the first transistor and a first switch unit. The fourth transistor is coupled to the second transistor and the first switch unit. The first control signal is used for controlling whether to turn on the first switch unit to substantially connect the third transistor and the first transistor in parallel and to substantially connect the fourth transistor and the second transistor in parallel, so as to adjust the trans-conductance value of the voltage controlled oscillator. The first transistor, the second transistor, the third transistor, and the fourth transistor are each a PMOS or an NMOS.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a voltage controlled oscillator according to a first embodiment of the present invention.

FIG. 2 is a diagram illustrating a relationship between the resonance frequency and the number of conducted transistor pairs.

FIG. 3 is a diagram illustrating a relationship between the swing of the voltage controlled oscillator shown in FIG. 1 and the number of conducted transistor pairs.

FIG. 4 is a diagram of a voltage controlled oscillator according to a second embodiment of the present invention.

FIG. 5 is a diagram of a voltage controlled oscillator according to a third embodiment of the present invention.

### DETAILED DESCRIPTION

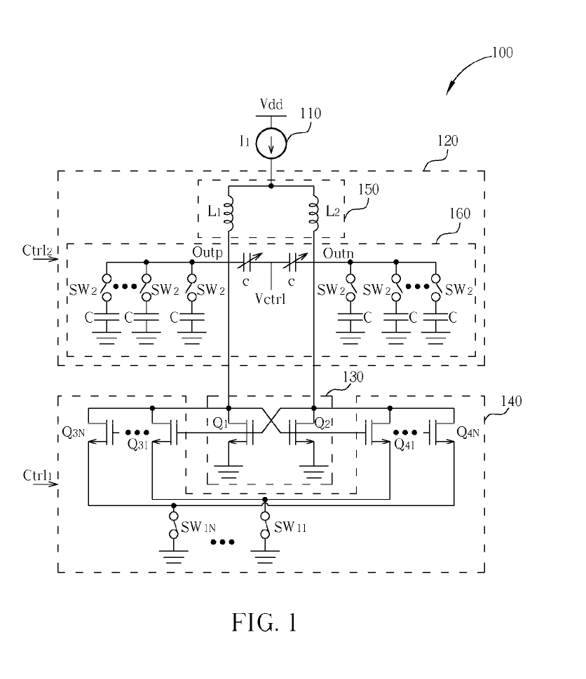

Please refer to FIG. 1. FIG. 1 is a diagram of a voltage controlled oscillator 100 according to a first embodiment of the present invention. The voltage controlled oscillator 100 includes, but is not limited to, a current source 110, an LC-tank circuit 120, a cross-coupled pair circuit 130, and a trans-conductance adjusting circuit 140. The current source 110 is coupled between a supply voltage terminal V_{dd} and the LC-tank circuit 120 for providing a bias current I₁. The LC-tank circuit 120 includes an inductor unit 150 and a switchable capacitor unit 160, which are respectively used for providing an inductance and a capacitance to determine a resonance frequency f₀. The inductor unit 150 includes a first inductor L₁ and a second inductor L₂, which are coupled to the current source 110 in parallel. The switchable capacitor unit 160 is coupled to the inductor unit 150 and includes a plurality of capacitors C and a plurality of corresponding second switches SW2. Each capacitor C is coupled to each other in parallel. Each second switch SW2 is used for controlling its corresponding capacitor C according to a control signal Ctrl₂. The cross-coupled pair circuit 130 is coupled to the LC-tank circuit 120 and has a first transistor Q₁ and a second transistor Q₂ in a cross-coupled manner. The trans-conductance adjusting circuit 140 is used for adjusting a trans-conductance value gₘ of the voltage controlled oscillator 100. The trans-conductance adjusting circuit 140 includes a plurality of transistor pairs and a plurality of corresponding first switches SW₁₁-SW_{1N}. Each transistor pair includes a third transistor Q₃₁-Q_{3N} and a corresponding fourth transistor Q₄₁-Q_{4N}. The first switch (SW₁₁-SW_{1N}) that each transistor pair corresponds to is used for controlling whether the third transistor (Q₃₁-Q_{3N}) of the transistor pair and the first transistor Q₁ are substantially connected in parallel and whether the fourth transistor (Q₄₁-Q_{4N}) of the transistor pair and the second transistor Q₂ are substantially connected in parallel, so as to adjust the trans-conductance value gₘ of the voltage controlled oscillator 100 according to a control signal Ctrl₁. For example, if a first switch, such as the first switch SW₁₁, is turned on, the bias current I₁ provided by the current source 110 flows through the LC-tank circuit 120, the third transistor Q₃₁ or the fourth transistor Q₄₁ of the trans-conductance adjusting circuit 140. Therefore, the third transistor Q₃₁ and the first transistor Q₁ are substantially connected in parallel, and the fourth transistor Q₄₁ and the second transistor Q₂ are substantially connected in parallel. In such situation, although a source of the third transistor Q₃₁ is not actually connected to a source of the first transistor Q₁, the source voltage of the third transistor Q₃₁ is substantially equal to the source voltage of the first transistor Q₁ (for example, both are the grounding voltage). Hence, the third transistor Q₃₁ can be viewed as substantially connected to the first transistor Q₁ in parallel. Similarly, the fourth transistor Q₄₁ can be viewed as substantially connected to the second transistor Q₂ in parallel.

In addition, each of the abovementioned second switches SW2 can be implemented by a transistor, and each of the first switches SW₁₁-SW_{1N} can be implemented by a transistor. But this should not be a limitation of the present invention and they can also be implemented by switch elements of other types.

In this embodiment, the voltage controlled oscillator 100 has a gain A, which can be represented by the equation listed in the following:

A=2×gₘ×Z_{P} (1)

The symbol gₘ is the trans-conductance value of the voltage controlled oscillator 100, and the symbol Z_{P} can be represented by another equation listed below:

$${Z}_{P} = \frac{{L}_{P}}{{C}_{P}} \times \frac{1}{{R}_{S}} \qquad ( 2 )$$

From the equations (1) and (2) above, one equation can be obtained:

$$A = 2 \times {g}_{m} \times \frac{{L}_{P}}{{C}_{P}} \times \frac{1}{{R}_{S}} \qquad ( 3 )$$

Assume that the equivalent inductance L_{P} and the equivalent resistance R_{S} of the voltage controlled oscillator 100 are fixed, thus the gain A is relative to the equivalent capacitance C_{P} and the trans-conductance value gₘ. The gain A decreases as the equivalent capacitance C_{P} increases, and the gain A increases as the equivalent capacitance C_{P} decreases. On the other hand, the gain A increases as the trans-conductance value gₘ increases, and the gain A decreases as the trans-conductance value gₘ decreases. As can be seen, the gain A (the swing of the voltage controlled oscillator 100) can be adjusted by adjusting the equivalent capacitance C_{P} and the trans-conductance value gₘ of the voltage controlled oscillator 100.

In the following, operations of controlling each transistor pair within the trans-conductance adjusting circuit 140 to adjust the trans-conductance value gₘ and the swing of voltage controlled oscillator 100 is further detailed. In a first situation, assume that the number of conducted first switches SW₁₁-SW_{1N} is increased. At this time, the trans-conductance value gₘ becomes larger. Because the gate-source voltage of the transistor is greater than the threshold voltage (i.e., Vₐₛ>Vₜ), the parasitic capacitor between the gate and the source of the transistor (Cₐₛ) increases. Therefore, the equivalent capacitance C_{P} of the voltage controlled oscillator 100 also increases, which causes the resonance frequency f₀ to decrease. As seen from the abovementioned equation (3), the increase of the trans-conductance gₘ is used for compensating for the decrease of the gain A resulting from the increase of the equivalent capacitance C_{P}. Therefore, the swing of the voltage controlled oscillator 100 is substantially unchanged (although slight errors and variations are acceptable).

In a second situation, assume that the number of conducted first switches SW₁₁-SW_{1N} is decreased. At this time, the trans-conductance value gₘ becomes smaller. Because the gate-source voltage of the transistor is smaller than the threshold voltage (i.e., Vₐₛ<Vₜ), the parasitic capacitor between the gate and the source of the transistor (Cₐₛ) decreases. Therefore, the equivalent capacitance C_{P} of the voltage controlled oscillator 100 also decreases, causing the resonance frequency f₀ to increase. As known from the abovementioned equation (3), the decrease of the trans-conductance gₘ is used for compensating for the increase of the gain A resulting from the decrease of the equivalent capacitance C_{P}. Thereby, the swing of the voltage controlled oscillator 100 is approximately unchanged.

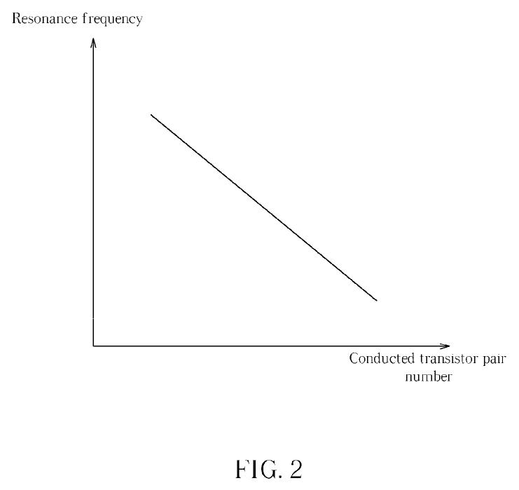

Thus, it can be seen that the resonance frequency f₀ can be adjusted through controlling the number of conducted first switches SW₁₁-SW_{1N}, and that a relationship between them can be obtained. Please refer to FIG. 2. FIG. 2 is a diagram illustrating a relationship between the resonance frequency f₀ and the number of conducted transistor pairs. As shown in FIG. 2, when the voltage controlled oscillator 100 is to be operated under the resonance frequency f₀ of a higher frequency, the number of conducted first switches SW₁₁-SW_{1N} should be decreased. On the other hand, when the voltage controlled oscillator 100 is to be operated under the resonance frequency f₀ of a lower frequency, the number of conducted first switches SW₁₁-SW_{1N} should be increased.

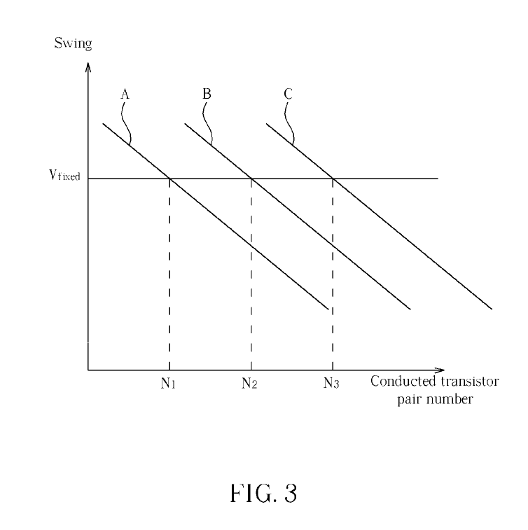

Please refer to FIG. 3. FIG. 3 is a diagram illustrating a relationship between the swing of the voltage controlled oscillator 100 shown in FIG. 1 and the number of conducted transistor pairs. Assume that the voltage controlled oscillator 100 is to be maintained at a fixed swing V_{fixed}. When the resonance frequency f₀ operates under different frequencies, the number of conducted transistor pairs of different values should be set. For example, when the voltage controlled oscillator 100 is to be operated under the resonance frequency f₀ of a higher frequency (such as the curve A), a number N₁ of conducted transistor pairs corresponding to the fixed swing V_{fixed} can be obtained at this time. When the voltage controlled oscillator 100 is to be operated under the resonance frequency fₒ of a lower frequency (such as the curve C), a number N₃ of conducted transistor pairs corresponding to the fixed swing V_{fixed} can be obtained at this time. Thus, it can be seen that when the voltage controlled oscillator 100 is to be operated under the different resonance frequencies and maintained at a fixed swing V_{fixed} simultaneously, such goals can be achieved by adjusting the number of conducted transistor pairs.

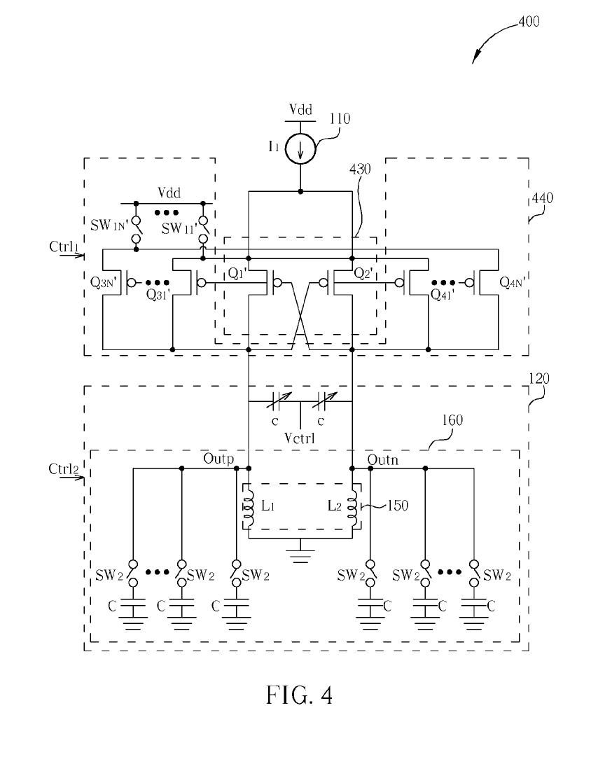

In the first embodiment of the present invention, the first transistor Q₁, the second transistor Qr., the third transistors Q3-MEN, and the fourth transistors Q41-Q4N are each an NMOS, but those skilled in the art should know that this is not a limitation of the present invention. Please refer to FIG. 4. FIG. 4 is a diagram of a voltage controlled oscillator 400 according to a second embodiment of the present invention. The voltage controlled oscillator 400 is similar to the voltage controlled oscillator 100 shown in FIG. 1. The difference between them is that a cross-coupled pair circuit 430 of the voltage controlled oscillator 400 includes a first transistor Q₁′, a second transistor Q₂′, and a trans-conductance adjusting circuit 440 of the voltage controlled oscillator 400 that includes a plurality of third transistors Q₃₁′-Q_{3N}′ and a plurality of corresponding fourth transistors Q₄₁′-Q_{4N}′, wherein the transistors included are implemented by a PMOS. Furthermore, the cross-coupled pair circuit 430 and the trans-conductance adjusting circuit 440 are coupled between the current source 110 and the LC-tank circuit 120.

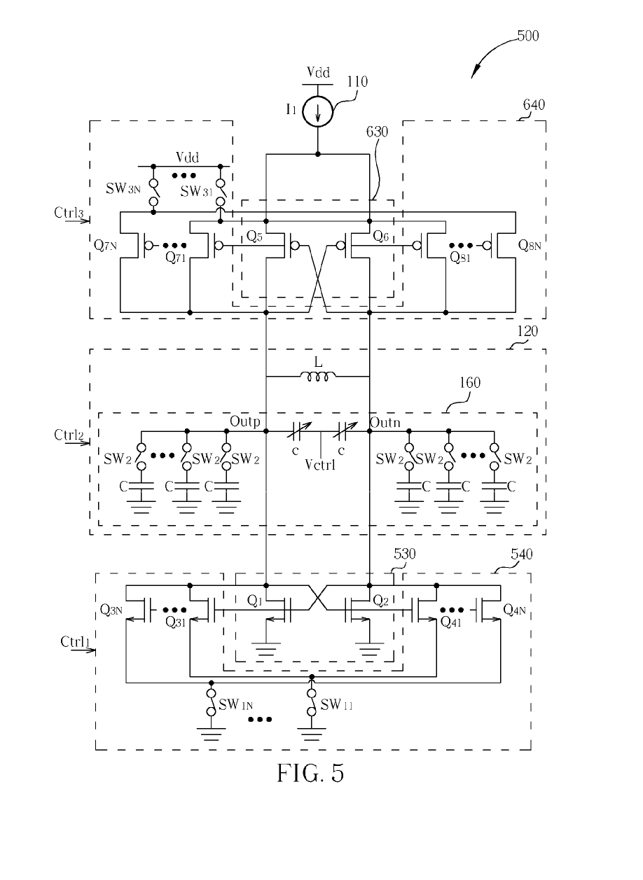

Of course, both the PMOS and the NMOS can be simultaneously applied to the voltage controlled oscillator. Please refer to FIG. 5. FIG. 5 is a diagram of a voltage controlled oscillator 500 according to a third embodiment of the present invention. The voltage controlled oscillator 500 is similar to the voltage controlled oscillator 100 shown in FIG. 1. The difference between them is that the voltage controlled oscillator 500 includes a first cross-coupled pair circuit 530, a second cross-coupled pair circuit 630, a first trans-conductance adjusting circuit 540, and a second trans-conductance adjusting circuit 640. Furthermore, in each transistor included in the first cross-coupled pair circuit 530 and in the first trans-conductance adjusting circuit 540 (i.e., the first transistor Q₁, the second transistor Q₂, the third transistors Q₃₁-Q_{3N}, and the fourth transistors Q₄₁-Q_{4N}) is implemented by an NMOS (the same as the cross-coupled pair circuit 130 and the trans-conductance adjusting circuit 140 shown in FIG. 1) and the first switches SW₁₁-SW_{1N} are controlled by the control signal Ctrl₁, and each transistor included in the second cross-coupled pair circuit 630 and in the second trans-conductance adjusting circuit 640 (i.e., the fifth transistor Q₅, the sixth transistor Q₆, the seventh transistors Q₇₁-Q_{7N}, and the eighth transistors Q₈₁-Q_{8N}) is implemented by a PMOS (the same as the cross-coupled pair circuit 430 and the trans-conductance adjusting circuit 440 shown in FIG. 4) and the third switches SW₃₁-SW_{3N} are controlled by the control signal Ctrl₃. The abovementioned second trans-conductance adjusting circuit 640 is used for adjusting the trans-conductance value gₘ of the voltage controlled oscillator 600 together with the first trans-conductance adjusting circuit 540.

Please note that, those skilled in the art should observe that various modifications and alterations of the first cross-coupled pair circuit 530, the second cross-coupled pair circuit 630, the first trans-conductance adjusting circuit 540, and the second trans-conductance adjusting circuit 640 may be made without departing from the spirit of the present invention. For example, each transistor included in the first cross-coupled pair circuit 530 and in the first trans-conductance adjusting circuit 540 can be implemented by a PMOS and each transistor included in the second cross-coupled pair circuit 630 and in the second trans-conductance adjusting circuit 640 can be implemented by an NMOS.

In addition, the connection manners of all the transistors mentioned in the embodiments of the present invention, including the connection manners of the gate, grain, and source of the transistors, are already shown in appending figures, and are therefore not detailed herein for brevity.

The abovementioned embodiments are presented merely for describing technology features of the present invention, and should in no way be considered to be limitations of the scope of the present invention. Each of the abovementioned second switch SW2 can be implemented by a transistor, each of the first switches SW₁₁-SW_{1N}, SW₁₁′-SW_{1N}′ can be implemented by a transistor, and each of the third switches SW₃₁-SW_{3N}, SW₃₁′-SW_{3N}′ can be implemented by a transistor, but is not limited to this only and can be switch elements of other types. Please note that, each of the abovementioned transistors can be an NMOS or a PMOS, but this should not be a limitation of the present invention. In addition, both the PMOS and the NMOS can be simultaneously applied to the voltage controlled oscillator. Those skilled in the art should observe that various modifications and alterations of the first cross-coupled pair circuit 530, the second cross-coupled pair circuit 630, the first trans-conductance adjusting circuit 540, and the second trans-conductance adjusting circuit 640 may be made without departing from the spirit of the present invention.

Furthermore, although the third transistor Q₃₁-Q_{3N} and the fourth transistor Q₃₁-Q_{3N} share the same first switch SW₁₁-SW_{1N} in the embodiments above, it can also be implemented if they are respectively coupled to their corresponding switches. For example, the third transistor Q₃₁ is coupled to one switch and the fourth transistor Q₄₁ is coupled to another switch, wherein the two switches can be turned on simultaneously by control signals to substantially connect the third transistor Q₃₁ and the first transistor Q₁ in parallel, and to substantially connect the fourth transistor Q₄₁ and the second transistor Q₂ in parallel when adjusting the trans-conductance value of the voltage controlled oscillator. Such connection manner and operating manner also belong to the scope of the present invention.

In summary, the present invention provides a voltage controlled oscillator. By adjusting the number of conducted first switches SW₁₁-SW_{1N} of the trans-conductance adjusting circuit 140, the trans-conductance value gₘ of the voltage controlled oscillator 100 can be adjusted and the equivalent capacitance C_{P} of the voltage controlled oscillator 100 can be changed. In other words, the resonance frequency f₀ also changes. When the resonance frequency f₀ is to be decreased, the number of conducted first switches SW₁₁-SW_{1N} should be increased. On the other hand, when the resonance frequency f₀ is to be increased, the number of conducted first switches SW₁₁-SW_{1N} should be decreased. The variation of the trans-conductance gₘ is used for compensating for the decrease or the increase of the gain A resulting from the variation of the equivalent capacitance C_{P}. Thereby, the swing of the voltage controlled oscillator 100 is approximately unchanged (slight errors and variations are acceptable). The voltage controlled oscillator disclosed in the present invention adjusts the resonance frequency f₀ through adjusting the number of conducted first switches SW₁₁-SW_{1N} of the trans-conductance adjusting circuit 140. Because the swing of the voltage controlled oscillator maintains at substantially a fixed value, such problems as being unable to oscillate in lower frequency will not occur. Furthermore, the voltage controlled oscillator disclosed in the present invention won't result in disadvantages such as larger current consumption, increased area, or decreased Q value, or poor phase noise.

Those skilled in the art will readily observe that numerous modifications and alterations of the device and method may be made while retaining the teachings of the invention.

What is claimed is:

1. A voltage controlled oscillator comprising:
an LC-tank circuit, for providing an inductance and a capacitance;
a cross-coupled pair circuit, coupled to the LC-tank circuit, having a first transistor and a second transistor in a cross-coupled manner; and
a trans-conductance adjusting circuit, coupled to the cross-coupled pair circuit, for adjusting a trans-conductance value of the voltage controlled oscillator according to a first control signal, the trans-conductance adjusting circuit comprises:
a third transistor, coupled to the first transistor and a first switch unit; and
a fourth transistor, coupled to the second transistor and the first switch unit;
wherein the first control signal is utilized for controlling the first switch unit to adjust the trans-conductance value of the voltage controlled oscillator.

2. The voltage controlled oscillator of claim 1, further comprising:
a current source, for providing a bias current to the LC-tank circuit and the cross-coupled pair circuit;
wherein when the first switch unit is turned on, the bias current flows through the third transistor or the fourth transistor.

3. The voltage controlled oscillator of claim 2, wherein a gate of the first transistor is coupled to a drain of the second transistor; and a gate of the second transistor is coupled to a drain of the first transistor.

4. The voltage controlled oscillator of claim 3, wherein a gate of the third transistor is coupled to the gate of the first transistor; a drain of the third transistor is coupled to the drain of the first transistor; a source of the third transistor is coupled to the first switch unit; a gate of the fourth transistor is coupled to the gate of the second transistor; a drain of the fourth transistor is coupled to a drain of the second transistor; and a source of the fourth transistor is coupled to the first switch unit.

5. The voltage controlled oscillator of claim 2, wherein the LC-tank circuit comprises:
an inductor unit, having a first inductor and a second inductor coupled to the current source; and
a switchable capacitor unit, coupled to the inductor unit, having a plurality of capacitors and a plurality of corresponding second switch units, wherein each second switch unit is utilized for controlling its corresponding capacitor.

6. The voltage controlled oscillator of claim 1, wherein the first transistor, the second transistor, the third transistor, and the fourth transistor are each a PMOS (P-type metal oxide semiconductor transistor).

7. The voltage controlled oscillator of claim 1, wherein the first transistor, the second transistor, the third transistor, and the fourth transistor are each an NMOS (N-type metal oxide semiconductor transistor).

8. The voltage controlled oscillator of claim 1, further comprising:
a second cross-coupled pair circuit, coupled to the LC-tank circuit, having a fifth transistor and a sixth transistor in a cross-coupled manner; and
a second trans-conductance adjusting circuit, for adjusting the trans-conductance value of the voltage controlled oscillator according to a third control signal, the second trans-conductance adjusting circuit comprising:
a seventh transistor, coupled to the fifth transistor and a third switch unit; and
an eighth transistor, coupled to the sixth transistor and the third switch unit;
wherein the third control signal is utilized for controlling whether to turn on the third switch unit to substantially connect the seventh transistor and the fifth transistor in parallel, and to substantially connect the eighth transistor and the sixth transistor in parallel, so as to adjust the trans-conductance value of the voltage controlled oscillator.

9. The voltage controlled oscillator of claim 8, wherein the first switch unit and the third switch unit each comprise at least one transistor switch.

10. The voltage controlled oscillator of claim 8, wherein the first transistor, the second transistor, the third transistor, and the fourth transistor are each a PMOS, and the fifth transistor, the sixth transistor, the seventh transistor, and the eighth transistor are each an NMOS.

11. The voltage controlled oscillator of claim 8, wherein the first transistor, the second transistor, the third transistor, and the fourth transistor are each an NMOS, and the fifth transistor, the sixth transistor, the seventh transistor, and the eighth transistor are each a PMOS.

12. The voltage controlled oscillator of claim 1, wherein the voltage controlled oscillator is disposed in a frequency synthesizer.
